(19) United States
(12) Patent Application Publication
(10) Pub. No.: US 2022/0137516 A1
(43) Pub. Date: May 5, 2022

(54) APPARATUS FOR TREATING SUBSTRATE AND METHOD FOR TREATING SUBSTRATE

(71) Applicant: SEMES CO., LTD., Chungcheongnam-do (KR)

(72) Inventors: Ho Shin KANG, Chungcheongnam-do (KR); Tae Woong SEO, Chungcheongnam-do (KR); Sung Min JO, Chungcheongnam-do (KR)

(21) Appl. No.: 17/513,115

(22) Filed: Oct. 28, 2021

(30) Foreign Application Priority Data
Oct. 29, 2020 (KR) 10-2020-0141876

(51) Int. Cl. G03F 7/20; H01L 21/677; G05B 19/418; G03F 7/40

(52) U.S. Cl. CPC G03F 7/7075; H01L 21/67703; G05B 2219/31276; G03F 7/40; G05B 19/4189

(57) ABSTRACT

Disclosed is a substrate treating apparatus including a coating module, an exposure module, a plurality of developing modules, and a transfer unit that performs transfer of a substrate between the modules. The plurality of developing modules include a plurality of post-exposure bake units that perform a bake process on a substrate on which an exposure process is completely performed in the exposure module. The substrate treating apparatus further includes a controller that controls the transfer of the substrate by the transfer unit. When transferring a substrate from the exposure module to the plurality of post-exposure bake units, the controller performs control to select a post-exposure bake unit in which the least delay time occurs, among the plurality of post-exposure bake units and to transfer the substrate to the selected post-exposure bake unit.

### CROSS-REFERENCE TO RELATED APPLICATIONS

A claim for priority under 35 U.S.C. § 119 is made to Korean Patent Application No. 10-2020-0141876 filed on Oct. 29, 2020, in the Korean Intellectual Property Office, the entire contents of which are hereby incorporated by reference.

### BACKGROUND

Embodiments of the inventive concept described herein relate to an apparatus for treating a substrate and a method for treating a substrate.

In manufacture of a semiconductor device, photolithography technology is used to form a circuit pattern on a semiconductor wafer. The formation of the circuit pattern using the photolithography technology is performed by forming a resist film on the wafer by applying resist, exposing the resist film to light to correspond to the circuit pattern by applying light to the resist film, and developing the resist film. The photolithography process is performed by a system in which an exposure apparatus is combined with a coating and developing apparatus that performs a series of processes including applying resist and developing the resist after exposure.

In general, in the so-called photo-lithography process of coating a semiconductor wafer with photoresist, exposing the photoresist to light, and developing the photoresist, a new process such as irradiation of deep ultraviolet light using photoresist for chemical amplification to integrate a wafer is being developed. In post-exposure bake (PEB) of a bake unit that is performed after exposure in the new process, working temperature and time management are very important factors in determination of critical dimension of a wafer. A wafer is loaded into and unloaded from process units through a predetermined time management technique (TACT) by a transfer robot in the sequence of exposure-PEB-Cool Plate (CP)-Wide Expose Edge (WEE)-developing-Hot Plate (HP) or in the sequence of exposure-WEE-PEB-CP-developing-HP. However, in the related art, in a process of loading a substrate into PEB performed after exposure, delay may occur when substrate treatment is delayed in the step next to the PEB.

### SUMMARY

Embodiments of the inventive concept provide a substrate transfer control method for efficiently treating a substrate.

The technical problems to be solved by the inventive concept are not limited to the aforementioned problems. Any other technical problems not mentioned herein will be clearly understood from the following description by those skilled in the art to which the inventive concept pertains.

According to an embodiment, a substrate treating apparatus includes a coating module, an exposure module, a plurality of developing modules, and a transfer unit that performs transfer of a substrate between the modules.

The plurality of developing modules include a plurality of post-exposure bake units that perform a bake process on a substrate on which an exposure process is completely performed in the exposure module. The substrate treating apparatus further includes a controller that controls the transfer of the substrate by the transfer unit. When transferring a substrate from the exposure module to the plurality of post-exposure bake units, the controller performs control to select a post-exposure bake unit in which the least delay time occurs, among the plurality of post-exposure bake units and to transfer the substrate to the selected post-exposure bake unit.

According to an embodiment, when transferring the substrate from the exposure module to the plurality of post-exposure bake units, the controller may perform control to perform an evasion process on the substrate in a case where it is determined that progress is impossible.

According to an embodiment, the evasion process may be a process of performing control to place the substrate in buffer modules inside the plurality of developing modules.

According to an embodiment, when transferring the substrate from the exposure module to the plurality of post-exposure bake units, the controller may perform control to retrieve the substrate from the buffer modules in a case where it is determined that progress is possible.

According to an embodiment, when slots in the buffer modules are all filled with evaded substrates, the controller may perform control such that a substrate is not loaded into the exposure module.

According to an embodiment, a substrate treating apparatus includes a coating module, an exposure module, a plurality of developing modules, and a transfer unit that performs transfer of a substrate between the modules.

The plurality of developing modules include a plurality of post-exposure bake units that perform a bake process on a substrate on which an exposure process is completely performed in the exposure module. The substrate treating apparatus further includes a controller that controls the transfer of the substrate by the transfer unit. When transferring a substrate from the exposure module to the plurality of post-exposure bake units, the controller performs control to select a control method in which delay time is least, among a first control method, a second control method, a third control method, and a fourth control method and to transfer the substrate.

According to an embodiment, in the first control method, the controller may perform control to directly load the substrate from the exposure module to the plurality of post-exposure bake units.

According to an embodiment, in the second control method, the controller may perform control to directly load the substrate from the exposure module to the plurality of post-exposure bake units and transfer the substrate to a cooling plate that is a next step.

According to an embodiment, in the third control method, the controller may perform control to perform an evasion process on the substrate in buffer modules inside the plurality of developing modules, when the substrate is not able to be loaded from the exposure module to the plurality of post-exposure bake units or when progress to a next step unit is impossible after the substrate is treated by the plurality of post-exposure bake units.

According to an embodiment, in the fourth control method, the controller may return the substrate from the buffer modules in which the evaded substrate is placed to the plurality of post-exposure bake units or the next step unit, when the evaded substrate exists in the buffer modules and the substrate is able to be loaded into the plurality of post-exposure bake units or the next step unit.

According to an embodiment, the evasion process may be a process of performing control to place the substrate in buffer modules.

According to an embodiment, when the buffer modules are all filled with evaded substrates, the controller may perform control such that a substrate is not loaded into the exposure module.

According to an embodiment, when the evaded substrates exist in the buffer modules, the controller may preferentially return the firstly evaded substrate in the buffer modules to the plurality of post-exposure bake units or the next step unit.

According to an embodiment, provided is a method for treating a substrate using a substrate treating apparatus including a coating module, an exposure module, a plurality of developing modules, and a transfer unit for transfer of the substrate between the modules.

The plurality of developing modules include a plurality of post-exposure bake units that perform a bake process on a substrate on which an exposure process is completely performed in the exposure module. The method includes determining whether a substrate is able to be transferred from the exposure module to the plurality of post-exposure bake units, performing controls to load the substrate from the exposure module to the plurality of post-exposure bake units, when it is determined that the substrate is able to be transferred, and performing control to perform an evasion process on the substrate, when it is determined that the substrate is not able to be transferred.

According to an embodiment, the determining of whether the substrate is able to be transferred from the exposure module to the plurality of post-exposure bake units may include determining whether there is a unit into which the substrate is able to be loaded, among the plurality of post-exposure bake units.

### BRIEF DESCRIPTION OF THE FIGURES

The above and other objects and features will become apparent from the following description with reference to the following figures, wherein like reference numerals refer to like parts throughout the various figures unless otherwise specified, and wherein:

FIG. 1 is a schematic perspective view illustrating a substrate treating apparatus according to an embodiment of the inventive concept;

FIG. 2 is a sectional view illustrating coating modules and developing modules of the substrate treating apparatus of FIG. 1;

FIG. 3 is a plan view of the substrate treating apparatus of FIG. 1;

FIG. 4 is a block diagram for explaining a substrate treating method in the related art;

FIG. 5 is a block diagram for explaining substrate treatment according to an embodiment of the inventive concept;

FIGS. 6A to 6D are block diagrams for explaining methods of treating substrates through different control methods; and

FIGS. 7A and 7B are views for explaining a result according to the substrate treating method in the related art and a result according to the substrate treating method of the inventive concept.

### DETAILED DESCRIPTION

Hereinafter, embodiments of the inventive concept will be described in detail with reference to the accompanying drawings such that those skilled in the art to which the inventive concept pertains can readily carry out the inventive concept. However, the inventive concept may be implemented in various different forms and is not limited to the embodiments described herein. Furthermore, in describing the embodiments of the inventive concept, detailed descriptions related to well-known functions or configurations will be omitted when they may make subject matters of the inventive concept unnecessarily obscure. In addition, components performing similar functions and operations are provided with identical reference numerals throughout the accompanying drawings.

The terms “include” and “comprise” in the specification are “open type” expressions just to say that the corresponding components exist and, unless specifically described to the contrary, do not exclude but may include additional components. Specifically, it should be understood that the terms “include”, “comprise”, and “have”, when used herein, specify the presence of stated features, integers, steps, operations, components, and/or parts, but do not preclude the presence or addition of one or more other features, integers, steps, operations, components, parts, and/or groups thereof.

The terms of a singular form may include plural forms unless otherwise specified. Furthermore, in the drawings, the shapes and dimensions of components may be exaggerated for clarity of illustration.

The terms such as first, second, and the like may be used to describe various components, but the components should not be limited by the terms. The terms may be used only for distinguishing one component from others. For example, without departing the scope of the inventive concept, a first component may be referred to as a second component, and similarly, the second component may also be referred to as the first component.

In the entire specification, the terminology, component “˜unit,” refers to a software component or a hardware component such as an FPGA or an ASIC, and performs at least one function or operation. It should be, however, understood that the component “˜unit” is not limited to a software or hardware component. The component “˜unit” may be implemented in storage media that can be designated by addresses. The component “˜unit” may also be configured to regenerate one or more processors.

For example, the component “˜unit” may include various types of components (e.g., software components, object-oriented software components, class components, and task components), processes, functions, attributes, procedures, sub-routines, segments of program codes, drivers, firmware, micro-codes, circuit, data, data base, data structures, tables, arrays, and variables. Functions provided by a component and the component “˜unit” may be separately performed by a plurality of components and components “˜units” and may also be integrated with other additional components.

Hereinafter, embodiments of the inventive concept will be described in more detail with reference to the accompanying drawings. The inventive concept may, however, be embodied in different forms and should not be construed as limited to the embodiments set forth herein. Rather, these embodiments are provided so that this disclosure will be thorough and complete, and will fully convey the scope of the inventive concept to those skilled in the art. In the drawings, the dimensions of components are exaggerated for clarity of illustration.

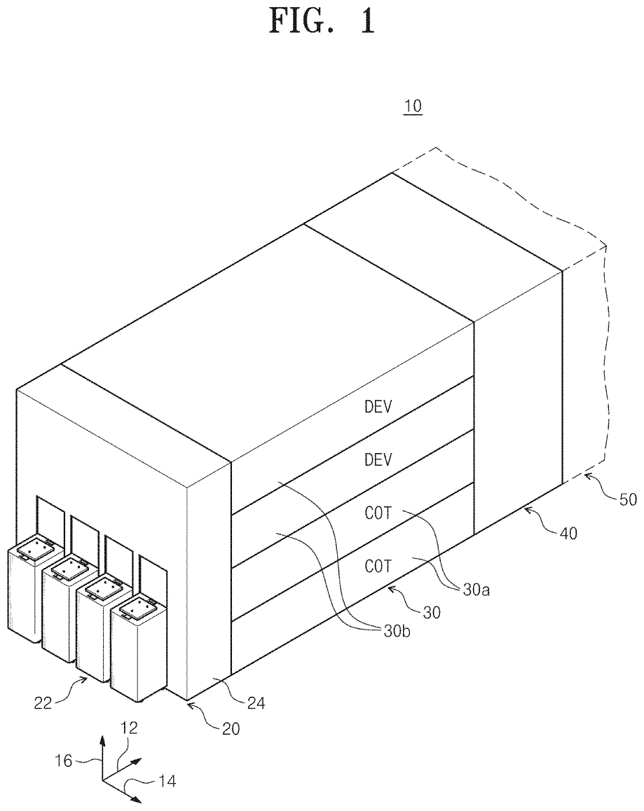

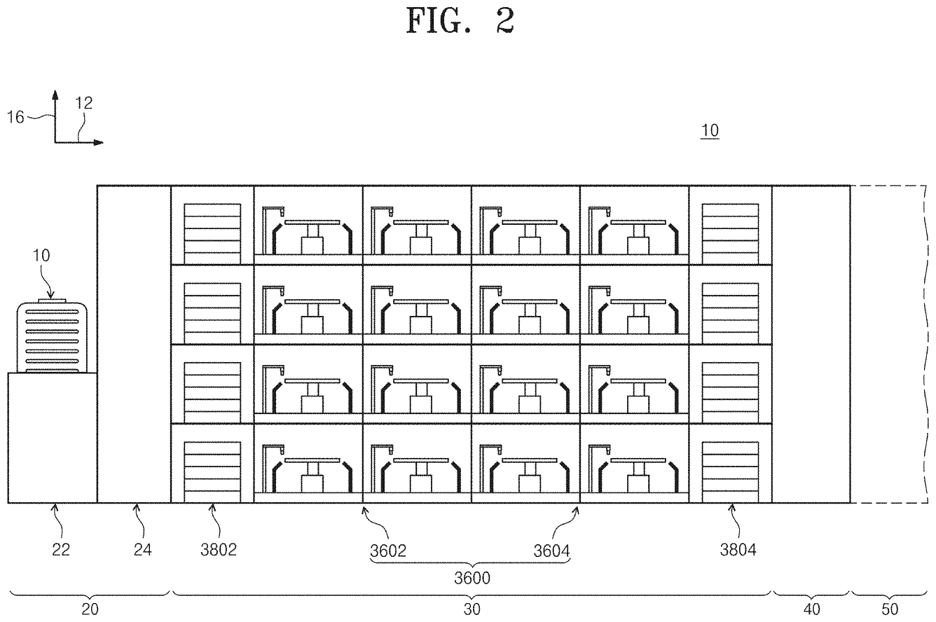

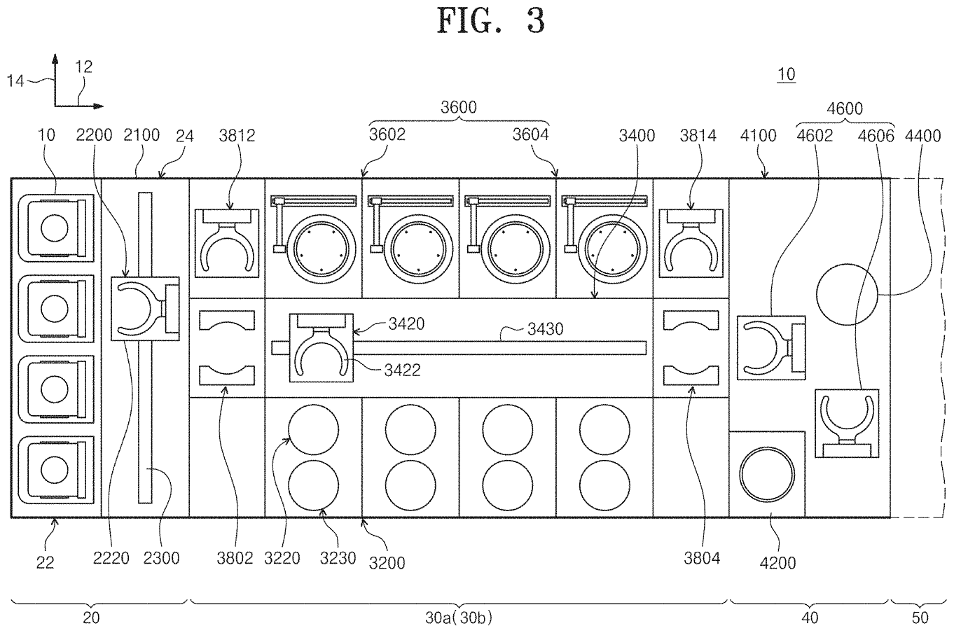

FIG. 1 is a schematic perspective view illustrating a substrate treating apparatus according to an embodiment of the inventive concept. FIG. 2 is a sectional view illustrating coating modules and developing modules of the substrate treating apparatus of FIG. 1. FIG. 3 is a plan view of the substrate treating apparatus of FIG. 1. Referring to FIGS. 1 to 3, the substrate treating apparatus 1 includes an index module 20, a treating module 30, and an interface module 40. According to an embodiment, the index module 20, the treating module 30, and the interface module 40 are sequentially disposed in a row. Hereinafter, a direction in which the index module 20, the treating module 30, and the interface module 40 are arranged is referred to as a first direction 12, a direction perpendicular to the first direction 12 when viewed from above is referred to as a second direction 14, and a direction perpendicular to both the first direction 12 and the second direction 14 is referred to as a third direction 16.

The index module 20 transfers substrates W from carriers 10 having the substrates W received therein to the treating module 30 and places the completely treated substrates W in the carriers 10. The index module 20 is disposed such that the lengthwise direction thereof is parallel to the second direction 14. The index module 20 has load ports 22 and an index frame 24. The load ports 22 are located on the opposite side to the treating module 30 with respect to the index frame 24. The carriers 10 having the substrates W received therein are placed on the load ports 22. The load ports 22 may be disposed in the second direction 14.

Airtight carriers 10 such as front open unified pods (FOUPs) may be used as the carriers 10. The carriers 10 may be placed on the load ports 22 by a transfer unit (not illustrated), such as an overhead transfer, an overhead conveyor, or an automatic guided vehicle, or by an operator.

An index robot 2200 is provided in the index frame 24. A guide rail 2300, the lengthwise direction of which is parallel to the second direction 14, is provided in the index frame 24. The index robot 2200 is movable on the guide rail 2300. The index robot 2200 includes a hand 2220 on which a substrate W is placed. The hand 2220 is movable forward and backward, rotatable about an axis facing the third direction 16, and movable in the third direction 16.

The treating module 30 performs a coating process and a developing process on the substrates W. The treating module 30 has the coating modules 30a and the developing modules 30b. The coating modules 30a perform the coating process on the substrates W, and the developing modules 30b perform the developing process on the substrates W. The coating modules 30a are stacked on each other. The developing modules 30b are stacked on each other. According to the embodiment of FIG. 1, two coating modules 30a and two developing modules 30b are provided. The coating modules 30a may be disposed under the developing modules 30b. According to an embodiment, the two coating modules 30a may perform the same process and may have the same structure. Furthermore, the two developing modules 30b may perform the same process and may have the same structure.

Referring to FIG. 3, each of the coating modules 30a has heat treatment chambers 3200, a transfer chamber 3400, liquid treatment chambers 3600, and buffer chambers 3800. The heat treatment chambers 3200 perform heat treatment processes on the substrates W. The heat treatment processes may include a cooling process and a heating process. The liquid treatment chambers 3600 form liquid films on the substrates W by dispensing a liquid onto the substrates W. The liquid films may be photoresist films or anti-reflection films. The transfer chamber 3400 transfers the substrates W between the heat treatment chambers 3200 and the liquid treatment chambers 3600 in the coating module 30a.

The transfer chamber 3400 is disposed such that the lengthwise direction thereof is parallel to the first direction 12. A transfer robot 3422 is provided in the transfer chamber 3400. The transfer robot 3422 transfers the substrates W between the heat treatment chambers 3200, the liquid treatment chambers 3600, and the buffer chambers 3800. According to an embodiment, the transfer robot 3422 has a hand 3420 on which a substrate W is placed, and the hand 3420 is movable forward and backward, rotatable about an axis facing the third direction 16, and movable in the third direction 16. A guide rail 3300, the lengthwise direction of which is parallel to the first direction 12, is provided in the transfer chamber 3400, and the transfer robot 3422 is movable on the guide rail 3300.

The heat treatment chambers 3200 are arranged in the first direction 12. The heat treatment chambers 3200 are located on one side of the transfer chamber 3400.

Referring to FIG. 2, some of the liquid treatment chambers 3600 may be stacked on each other. The liquid treatment chambers 3600 are disposed on an opposite side of the transfer chamber 3400. The liquid treatment chambers 3600 are arranged side by side in the first direction 12. Some of the liquid treatment chambers 3600 are located adjacent to the index module 20. Hereinafter, these liquid treatment chambers are referred to as the front liquid treatment chambers 3602. Other liquid treatment chambers 3600 are located adjacent to the interface module 40. Hereinafter, these liquid treatment chambers are referred to as the rear liquid treatment chambers 3604.

Each of the front liquid treatment chambers 3602 applies a first liquid to a substrate W, and each of the rear liquid treatment chambers 3604 applies a second liquid to the substrate W. The first liquid and the second liquid may be different types of liquids. According to an embodiment, the first liquid is an anti-reflection film, and the second liquid is photoresist. The photoresist may be applied to the substrate W coated with the anti-reflection film. Selectively, the first liquid may be photoresist, and the second liquid may be an anti-reflection film. In this case, the anti-reflection film may be applied to the substrate W coated with the photoresist. Selectively, the first liquid and the second liquid may be of the same type. Both the first liquid and the second liquid may be photoresist.

Some of the buffer chambers 3800 are disposed between the index module 20 and the transfer chamber 3400. Hereinafter, these buffer chambers are referred to as the front buffers 3802. The front buffers 3802 are stacked on each other in an up/down direction. The other buffer chambers 3800 are disposed between the transfer chamber 3400 and the interface module 40. These buffer chambers are referred to as the rear buffers 3804. The rear buffers 3804 are stacked on each other in the up/down direction. Each of the front buffers 3802 and the rear buffers 3804 temporarily stores a plurality of substrates W. The substrates W stored in the front buffers 3802 are loaded or unloaded by the index robot 2200 and the transfer robot 3422. The substrates W stored in the rear buffers 3804 are loaded or unloaded by the transfer robot 3422 and a first robot 4602.

Each of the developing modules 30b has heat treatment chambers 3200, a transfer chamber 3400, and liquid treatment chambers 3600. The heat treatment chambers 3200, the transfer chamber 3400, and the liquid treatment chambers 3600 of the developing module 30b are disposed in a structure substantially similar to the structure in which the heat treatment chambers 3200, the transfer chamber 3400, and the liquid treatment chambers 3600 of the coating module 30a are disposed. Therefore, descriptions thereabout will be omitted. However, the liquid treatment chambers 3600 in the developing module 30b are provided as developing chambers 3600, all of which identically perform a developing process on a substrate W by dispensing a developing solution onto the substrate W.

The developing module 30b may include a post-exposure unit bake unit that performs a bake process on a substrate completely exposed to light in an exposure module 50. The developing module 30b may include a buffer module that stores substrates inside the developing module 30b.

The interface module 40 connects the treating module 30 with the exposure module 50. The interface module 40 has an interface frame 4100, an additional process chamber 4200, an interface buffer 4400, and a transfer unit 4600.

The interface frame 4100 may have, at the top thereof, a fan filter unit that forms a downward air flow in the interface frame 4100. The additional process chamber 4200, the interface buffer 4400, and the transfer unit 4600 are disposed inside the interface frame 4100. Before a substrate W completely treated in the coating module 30a is transferred to the exposure module 50, the additional process chamber 4200 may perform a predetermined additional process on the substrate W. Selectively, before a substrate W completely treated in the exposure module 50 is transferred to the developing module 30b, the additional process chamber 4200 may perform a predetermined additional process on the substrate W. According to an embodiment, the additional process may be an edge exposing process of exposing an edge region of a substrate W to light, a top-side cleaning process of cleaning the top side of the substrate W, or a backside cleaning process of cleaning the backside of the substrate W. A plurality of additional process chambers 4200 may be provided. The additional process chambers 4200 may be stacked one above another. The additional process chambers 4200 may all perform the same process. Selectively, some of the additional process chambers 4200 may perform different processes.

The interface buffer 4400 provides a space in which a substrate W transferred between the coating module 30a, the additional process chambers 4200, the exposure module 50, and the developing module 30b temporarily stays. A plurality of interface buffers 4400 may be provided. The interface buffers 4400 may be stacked one above another.

According to an embodiment, the additional process chambers 4200 may be disposed on one side of an extension line facing the lengthwise direction of the transfer chamber 3400, and the interface buffers 4400 may be disposed on an opposite side of the extension line.

The transfer unit 4600 transfers a substrate W between the coating module 30a, the additional process chambers 4200, the exposure module 50, and the developing module 30b. The transfer unit 4600 may be implemented with one or more robots. According to an embodiment, the transfer unit 4600 has the first robot 4602 and the second robot 4606. The first robot 4602 may transfer a substrate W between the coating module 30a, the additional process chambers 4200, and the interface buffers 4400, an interface robot may transfer the substrate W between the interface buffers 4400 and the exposure module 50, and the second robot 4606 may transfer the substrate W between the interface buffers 4400 and the developing module 30b.

The first robot 4602 and the second robot 4606 each include a hand on which a substrate W is placed, and the hand is movable forward and backward, rotatable about an axis parallel to the third direction 16, and movable in the third direction 16.

The hands of the index robot 2200, the first robot 4602, and the second robot 4606 may all have the same shape as the hand 3420 of the transfer robot 3422. Selectively, a hand of a robot that directly exchanges a substrate W with a transfer plate 3240 of each heat treatment chamber 3200 may have the same shape as the hand 3420 of the transfer robot 3422, and hands of the remaining robots may have a different shape from the hand 3420 of the transfer robot 3422.

According to an embodiment, the index robot 2200 may directly exchange a substrate W with a heating unit 3230 of the front heat treatment chamber 3200 provided in the coating module 30a.

Furthermore, the transfer robots 3422 provided in the coating module 30a and the developing module 30b may directly exchange a substrate W with the transfer plate 3240 located in the heat treatment chamber 3200.

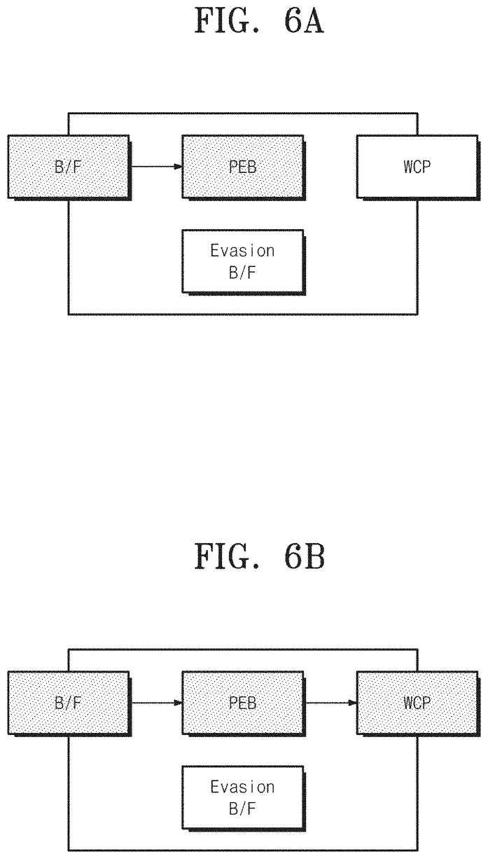

According to an embodiment, the substrate treating apparatus according to the inventive concept may further include a controller (not illustrated) that controls transfer of a substrate by a transfer unit. The controller may control a transfer unit that transfers a substrate from the exposure module 50 to the developing module 30b. A specific control method of the controller will be described below with reference to FIG. 5.

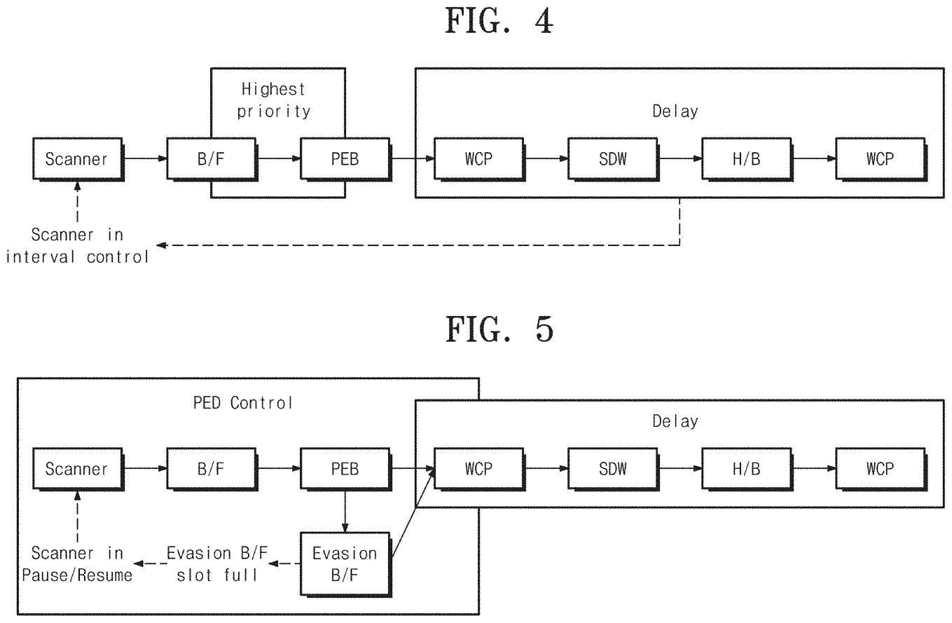

FIG. 4 is a block diagram for explaining a substrate treating method in the related art.

A developing module may perform a post-exposure baking (PEB) process, a developing process, and a hard baking process. These processes may be performed by units included in the developing module. The time from when a substrate is unloaded from a scanner when the substrate is loaded into a PEB unit is one of important management items.

Post-exposure baking delay (PED) time refers to the time from when the substrate is unloaded from the scanner to when the substrate is loaded into the PEB unit. According to an operating method in the related art, to manage the time from when the substrate is unloaded from the scanner to when the substrate is loaded into the PEB unit, a method of adjusting the time interval in which the substrate is loaded into the scanner, operating priority processing of the substrate that is loaded into the PEB unit, and limiting only a specific section in the developing module when a wafer is present in the developing module is used.

According to the method in the related art, when a wafer exists in a buffer module of the developing module after the substrate is unloaded from the scanner, a situation in which a wafer cannot be loaded into the PEB unit may occur. Due to this, post-exposure baking delay (PED) occurs.

Furthermore, when wafer transfer is delayed after substrate pick-up in the PEB unit due to process delay in a developing step and a hard baking step, PED of a wafer derived from the scanner may occur.

When an unused unit exists in the developing module, the developing module may fail to treat a wafer unloaded from the scanner. Therefore, cycle time of the developing module may be calculated, and the cycle time may be set as the interval in which the substrate is able to be loaded into the scanner.

However, in this case, there is a disadvantage of having to calculate the cycle time, and there is a high possibility that unexpected delay time occurs. Accordingly, a method for solving these problems is required.

FIG. 5 is a block diagram for explaining substrate treatment according to an embodiment of the inventive concept.

According to a substrate treating method of the inventive concept, in a section from a scanner to developing modules, the controller may select a developing module in which the fast PEB loading is possible, among the developing modules and may perform control to transfer a substrate.

Furthermore, according to the substrate treating method of the inventive concept, when it is determined that progress of a substrate unloaded from the scanner impossible, the controller may operate evasion and recovery of a substrate using an evasion slot in a buffer module. According to an embodiment, the buffer module may be disposed in the developing module. A buffer unit between the scanner and a PEB unit in FIG. 5 may be a unit capable of temporarily storing a substrate when the substrate is transferred between the scanner and the PEB unit, and the buffer module Evasion B/F of FIG. 5 may be a buffer module included in the developing module.

According to FIG. 5, for the purpose of minimizing the time taken before a WCP step, the controller may perform control such that a substrate is treated in the order of the scanner, the PEB unit, and the WCP when progress to the PEB unit is possible, or may perform control to evade a substrate in the buffer module inside the developing module when progress to the PEB unit or a unit next to the PEB unit is impossible, thereby efficiently performing substrate treatment.

In the existing case, a substrate has to continually stand by in the PEB unit even when step progress is impossible, and therefore there is a delay phenomenon. However, in the case of the inventive concept, the controller may perform control to evade a substrate according to situations when it is determined that step progress is impossible, thereby having an effect of minimizing delay.

Furthermore, referring to FIG. 5, when an evasion slot, that is, a residual slot is left in the buffer module inside the developing module, the controller may perform control to continually load a substrate into the scanner.

That is, according to the inventive concept, the controller may control transfer of a substrate from when the substrate is unloaded from the scanner to when the substrate is loaded into the PEB module, thereby having an effect of efficiently treating the substrate in terms of time, compared to the related art.

In the following cases, the controller according to the inventive concept determines that progress is impossible and performs an evasion process.

According to an embodiment, when progress to a next step unit is impossible after the PEB step, the controller may perform an evasion process. In this case, a substrate being treated may be present in the next step unit.

According to an embodiment, when an evaded substrate exists in a buffer module inside a corresponding developing module before and after the PEB step, the controller may perform control to perform an evasion process. The reason for this is for prevention of overtaking of a substrate or a lot.

According to an embodiment, when progress to the next step unit is possible after the PEB step, the controller may perform control to perform an evasion process in a case where overtaking of a lot is expected.

According to an embodiment, in the above case, the controller may determine that progress is impossible and may perform control to perform evasion of a substrate. The evasion may be performed by placing a substrate in a buffer module included in each of a plurality of developing modules. According to an embodiment, the evasion may be the placement of a substrate in a slot in a buffer module.

The controller may perform control to recover an evaded substrate from the developing module including the buffer module in which the evaded substrate is included, when it is determined that progress to the next step unit is possible. The recovery may be the transfer of the evaded substrate from the buffer module to the next step unit.

Hereinafter, first to fourth control methods in which the controller of the inventive concept controls whether to load a substrate will be described.

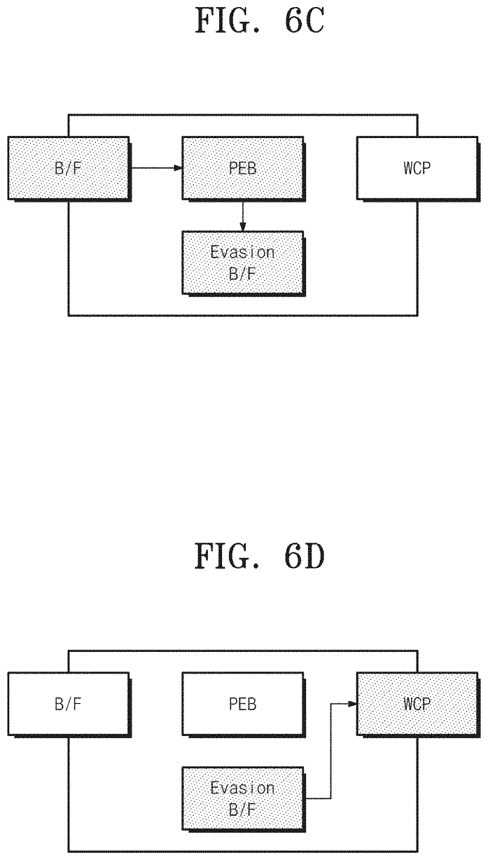

FIGS. 6A to 6D are block diagrams for explaining methods of treating substrates through different control methods.

FIG. 6A is a view for explaining treatment using the first control method among the substrate treating methods of the inventive concept.

According to FIG. 6A, in the first control method, the buffer unit located between the scanner and the PEB unit may pick a substrate, and the controller may select a unit in which PEB loading is possible and may perform control to place the substrate into the unit in which the PEB loading is possible. Thereafter, when next step treatment is possible, the controller may perform control to transfer the substrate to the next step. At this time, the selected unit may be a unit in which the least delay time occurs, among units in which PEB loading is possible.

FIG. 6B is a view for explaining treatment using the second control method among the substrate treating methods of the inventive concept.

According to FIG. 6B, in the second control method, the buffer unit may pick a substrate, and when an exchangeable wafer is present in the PEB unit, the controller may select the corresponding PEB unit and may perform control such that a wafer is loaded into the corresponding PEB unit. In this case, even though a wafer is present in the PEB unit, the controller may perform control such that treatment is immediately possible, when the wafer is exchangeable.

FIG. 6C is a view for explaining treatment using the third control method among the substrate treating methods of the inventive concept.

According to FIG. 6C, in the third control method, the buffer unit may pick a wafer, and the controller may determine whether an exchangeable wafer is present in the PEB unit. At this time, the controller may perform control to evade a substrate when there is no PEB unit in which progress is possible. Alternatively, the controller may perform control to evade a substrate when progress to a next step unit is impossible after PEB treatment ends. Accordingly, the controller may perform control to enable efficient wafer treatment without an increase in PED time.

FIG. 6D is a view for explaining treatment using the fourth control method among the substrate treating methods of the inventive concept.

According to FIG. 6D, in the fourth control method, the controller may perform control to pick a wafer in a buffer module in which a wafer evaded according to the third control method is included and to transfer the wafer to a next step.

The next steps described in FIGS. 6A to 6B refer to steps after the PEB step.

That is, according to the inventive concept, to control the PED time in the developing module, an operating section from the scanner to the PEB step may be divided into four types.

In a case where an evaded substrate is present in the buffer module, treatment of a wafer loaded into the scanner may be temporarily held when the number of evasion slots, that is, residual slots in the buffer module inside the developing module is smaller than the number of substrates unloaded from the scanner and wafers being treated between PEB steps.

In a case where an evaded substrate is present in the buffer module, the controller may perform control such that wafers are consistently loaded into the scanner, when the number of evasion slots, that is, residual slots in the buffer module inside the developing module is larger than the number of substrates unloaded from the scanner and wafers being treated between PEB steps.

According to an embodiment, when a wafer is unloaded from the scanner and distributed to a developing module, the wafer may be preferentially distributed to a developing module in which a place or exchange PEB unit exists and may be preferentially distributed to the firstly put developing module in the case of the same condition.

In the case of controlling a substrate through the first to fourth control methods, overtaking of a low is not permitted in all sections. In a case where an evaded substrate is present in the buffer module, evasion of a substrate picked by the PEB may be preferentially performed to prevent overtaking of the substrate. Furthermore, in a case where an evaded substrate is a substrate in the following job, progress to a next step unit may be made when a substrate picked by the PEB is a preceding job.

When a substrate evaded according to the fourth control method is recovered, overtaking of a substrate and overtaking of a lot are not permitted. When a substrate evaded according to the fourth control method is recovered, the recovery is possible when a substrate is able to be placed in the next step unit, that is, when there is an empty unit. When proceeding to the next step unit according to the fourth control method, the controller may not perform recovery in a case where a substrate is expected to stand by on a robot due to a process state or a state of a process unit.

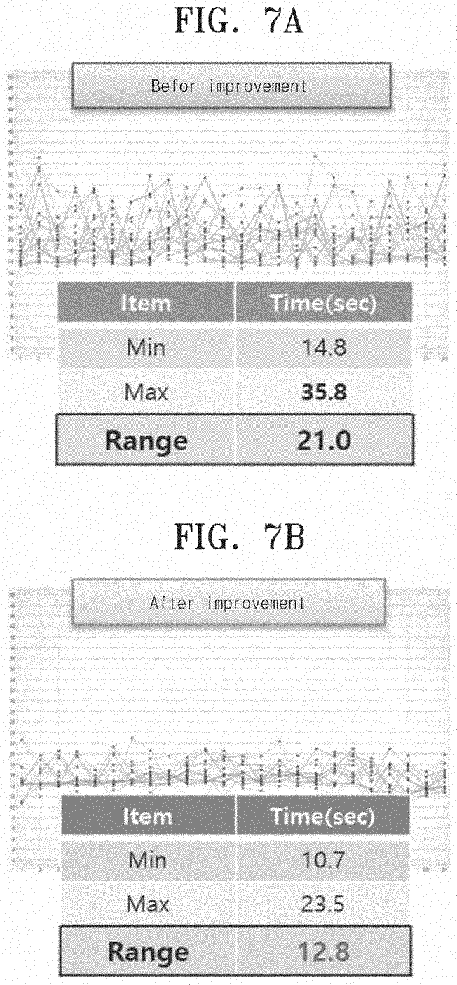

FIGS. 7A and 7B are views for explaining a result according to the substrate treating method in the related art and a result according to the substrate treating method of the inventive concept.

According to FIG. 7A, when substrate loading is controlled according to the substrate treating method in the related art, the minimum PED time is 14.8 seconds, the maximum PED time is 35.8 seconds, and the average PED time is 21.0 seconds.

However, according to FIG. 7B, in the case of the substrate treating method of the inventive concept, the minimum PED time is 10.7 seconds, the maximum PED time is 23.5 seconds, and the average PED time is 12.8 seconds

That is, it can be seen that when control of substrate loading is performed by using the substrate treating method of the inventive concept, there is an effect of lowering the maximum PED time and significantly decreasing the average PED time.

According to the inventive concept, disclosed is the substrate transfer control method for efficiently treating a substrate.

The inventive concept has an efficient effect in terms of time, compared to the method in the related art.

Effects of the inventive concept are not limited to the above-described effects. Any other effects not mentioned herein may be clearly understood from this specification and the accompanying drawings by those skilled in the art to which the inventive concept pertains.

Although the embodiments of the inventive concept have been described above, it should be understood that the embodiments are provided to help with comprehension of the inventive concept and are not intended to limit the scope of the inventive concept and that various modifications and equivalent embodiments can be made without departing from the spirit and scope of the inventive concept. The drawings provided in the inventive concept are only drawings of the optimal embodiments of the inventive concept. The scope of the inventive concept should be determined by the technical idea of the claims, and it should be understood that the scope of the inventive concept is not limited to the literal description of the claims, but actually extends to the category of equivalents of technical value.

While the inventive concept has been described with reference to embodiments, it will be apparent to those skilled in the art that various changes and modifications may be made without departing from the spirit and scope of the inventive concept. Therefore, it should be understood that the above embodiments are not limiting, but illustrative.

1. A substrate treating apparatus comprising:
a coating module;
an exposure module;
a plurality of developing modules: and
a transfer unit configured to perform transfer of a substrate between the modules,
wherein the plurality of developing modules include a plurality of post-exposure bake units configured to perform a bake process on a substrate on which an exposure process is completely performed in the exposure module,
wherein the substrate treating apparatus further comprises a controller configured to control the transfer of the substrate by the transfer unit, and
wherein when transferring the substrate from the exposure module to the plurality of post-exposure bake units, the controller performs control to select a post-exposure bake unit in which the least delay time occurs, among the plurality of post-exposure bake units and to transfer the substrate to the selected post-exposure bake unit.

2. The substrate treating apparatus of claim 1, wherein when transferring the substrate from the exposure module to the plurality of post-exposure bake units, the controller performs control to perform an evasion process on the substrate in a case where it is determined that progress is impossible.

3. The substrate treating apparatus of claim 2, wherein the evasion process is a process of performing control to place the substrate in buffer modules inside the plurality of developing modules.

4. The substrate treating apparatus of claim 3, wherein when transferring the substrate from the exposure module to the plurality of post-exposure bake units, the controller performs control to retrieve the substrate from the buffer modules in a case where it is determined that progress is possible.

5. The substrate treating apparatus of claim 3, wherein when slots in the buffer modules are all filled with evaded substrates, the controller performs control such that a substrate is not loaded into the exposure module.

6. A substrate treating apparatus comprising:
a coating module;
an exposure module;
a plurality of developing modules: and
a transfer unit configured to perform transfer of a substrate between the modules,
wherein the plurality of developing modules include a plurality of post-exposure bake units configured to perform a bake process on a substrate on which an exposure process is completely performed in the exposure module,
wherein the substrate treating apparatus further comprises a controller configured to control the transfer of the substrate by the transfer unit, and
wherein when transferring the substrate from the exposure module to the plurality of post-exposure bake units, the controller performs control to select a control method in which delay time is least, among a first control method, a second control method, a third control method, and a fourth control method and to transfer the substrate.

7. The substrate treating apparatus of claim 6, wherein in the first control method, the controller performs control to directly load the substrate from the exposure module to the plurality of post-exposure bake units.

8. The substrate treating apparatus of claim 6, wherein in the second control method, the controller performs control to directly load the substrate from the exposure module to the plurality of post-exposure bake units and transfer the substrate to a cooling plate that is a next step.

9. The substrate treating apparatus of claim 6, wherein in the third control method, the controller performs control to perform an evasion process on the substrate in buffer modules inside the plurality of developing modules, when the substrate is not able to be loaded from the exposure module to the plurality of post-exposure bake units or when progress to a next step unit is impossible after the substrate is treated by the plurality of post-exposure bake units.

10. The substrate treating apparatus of claim 9, wherein in the fourth control method, the controller returns the substrate from the buffer modules in which the evaded substrate is placed to the plurality of post-exposure bake units or the next step unit, when the evaded substrate exists in the buffer modules and the substrate is able to be loaded into the plurality of post-exposure bake units or the next step unit.

11. The substrate treating apparatus of claim 9, wherein the evasion process is a process of performing control to place the substrate in buffer modules.

12. The substrate treating apparatus of claim 11, wherein when the buffer modules are all filled with evaded substrates, the controller performs control such that a substrate is not loaded into the exposure module.

13. The substrate treating apparatus of claim 12, wherein when the evaded substrates exist in the buffer modules, the controller preferentially returns the firstly evaded substrate in the buffer modules to the plurality of post-exposure bake units or the next step unit.

14.-18. (canceled)
